(19) United States
(12) Patent Application Publication
(10) Pub. No.: US 2015/0294711 A1
(43) Pub. Date: Oct. 15, 2015

(54) PERFORMING REFRESH OF A MEMORY DEVICE IN RESPONSE TO ACCESS OF DATA

(71) Applicant: HEWLETT-PACKARD DEVELOPMENT COMPANY, L.P., Houston, TX (US)

(72) Inventors: Blaine D. Gaither, Fort Collins, CO (US); Darel N. Emmot, Wellington, CO (US); Lidia Warnes, Roseville, CA (US)

(21) Appl. No.: 14/410,629

(22) PCT Filed: Oct. 22, 2012
(86) PCT No.: PCT/US2012/061257

§ 371 Date: Dec. 23, 2014

(51) Int. Cl. G11C 11/406; G11C 7/10

(52) U.S. Cl. CPC G11C 11/40618; G11C 7/1072

(57) ABSTRACT

An access of data in a memory device is sampled. In response to the sampled access of data, a refresh operation is performed in the memory device.

### BACKGROUND

A memory device includes memory cells to store data values. An example type of memory device is a dynamic random access memory (DRAM) device. As memory manufacturing technology has advanced, the feature size of memory cells has decreased to increase the density of memory cells in a memory device. Increasing the memory cell density provides increased storage capacity in memory device.

### BRIEF DESCRIPTION OF THE DRAWINGS

Some embodiments are described with respect to the following figures:

FIG. 1 is a block diagram of an example arrangement that includes a memory device and a processing circuit according to some implementations;

FIG. 2 is a block diagram of an example memory device according to some implementations;

FIG. 3 is a flow diagram of a refresh control process according to some implementations; and

FIG. 4 is a block diagram of refresh control logic according to some implementations.

### DETAILED DESCRIPTION

As memory cells of memory devices have become denser due to decreasing feature sizes, the memory cells can become more sensitive to various noise sources that may corrupt the data stored in the memory cells. One type of noise source includes disturbance caused by data access operations, where data access operations performed on one group of memory cells may cause disturbance of at least another group of memory cells.

In some examples, a memory device can be a dynamic random access memory (DRAM) device, which has memory cells formed of storage capacitors and access transistors that can be activated or deactivated to control access of respective storage capacitors. A storage capacitor stores a voltage that corresponds to a respective data value (e.g. “0” or “1”). Although reference is made to DRAM devices in the ensuing discussion, it is noted that techniques or mechanisms according to some implementations can also be applied to other types of memory devices that may have other types of storage elements (different from storage capacitors).

In a DRAM device, a data access operation can activate a group (e.g. row or column) of memory cells, extract content from the group, and restore content back to the memory cells of the group. The process of activating and restoring content in the memory cells of the group can lead to disturbance of a neighboring group of cells.

For example, data access operations performed on one group of memory cells may disturb a neighboring group (or neighboring groups) of memory cells. For a given group of memory cells, repeated data access operations to neighboring groups of memory cells can result in repeated disturbances of the given group of memory cells. Such repeated disturbances may cause a data value stored in at least one of the memory cells in the given group to change, which leads to data corruption. For example, if the memory cell stores a voltage corresponding to a “0” or “1” data value, then the repeated disturbances may be sufficient to cause the data value represented by the voltage to change from a “0” to a “1”, or vice versa.

In some examples, a “group” of memory cells can refer to any collection of memory cells. The general notion is that one group of memory cells can be disturbed due to data access operations performed on at least one neighboring group of memory cells. A “data access operation” or “an access of data” refers to an operation in which data of the memory cell is accessed, either as part of a read operation and/or a write operation.

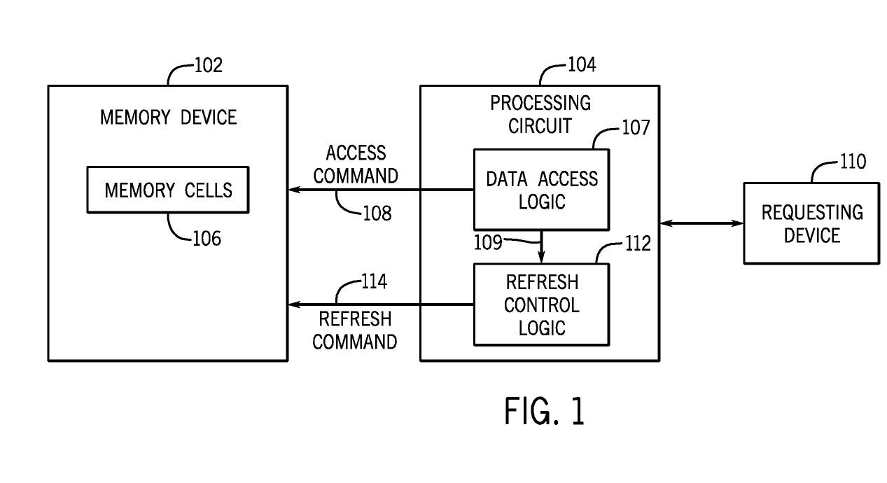

FIG. 1 is a block diagram of an example arrangement that includes a memory device 102 and a processing circuit 104. The arrangement of FIG. 1 can be part of a system, such as a computer, a tablet a smartphone, a game appliance, and so forth. The memory device 102 includes memory cells 106, which can store respective data values. Data in the memory cells 106 are accessible in response to commands from a processing circuit 104. In some examples, the processing circuit 104 can be part of a memory controller.

As depicted in FIG. 1, the processing circuit 104 includes data access logic 107, which is able to issue an access command 108 to the memory device 102 to access memory location(s) in the memory device 102. The access command 108 can be issued by the data access logic 107 in response to a request from a requesting device 110, can be a processor input/output device, and so forth.

The processing circuit 104 also includes refresh control logic 112, which is able to issue a refresh command 114 to the memory device 102 to perform a refresh operation in the memory device 102. The refresh command 114 can be issued by the refresh control logic 112 in response to accesses of data (communicated over 109). As discussed further below, the refresh control logic 112 is able to issue the refresh command 114 to perform a refresh operation to address the issue of data corruption that may be potentially caused by disturbances due to data access operations in the memory device 102.

Note that the access command 108 and refresh command 114 can be communicated over common address and control lines, in some implementations. Also, FIG. 1 does not depict data lines that can be connected between the memory device 102 and processing circuit 104 to carry data, including read data or write data.

In a memory device such as a DRAM device, the voltage stored in a memory cell 106 can he maintained at the correct level by performing periodic refresh. Refreshing a memory cell refers to reinforcing the voltage in the memory cell to counteract potential corruption of data resulting from current leakage from the storage capacitor of the memory cell. If the voltage stored in the memory cell represents a “1” data value, then refreshing the memory cell causes the voltage to be increased so that the voltage provides a more reliable representation of “1”. On the other hand, if the voltage stored in the memory cell represents a “0” data value, then refreshing the memory cell causes the voltage to be reduced to provide a more reliable representation of “0”. Refreshing memory cells improves the integrity of data values represented by the memory cells. In other examples, a “1” data value can be represented by a low voltage while a “0” data value can be represented by a high voltage.

Periodic refresh can be provided such that any given memory cell 106 in the memory device 102 is refreshed at least once every specified time interval. This periodic refresh is performed to avoid data loss caused by current leakage from a memory cell. Periodic refresh can be governed by a particular refresh policy. In other examples, the particular refresh policy can cause refresh operations that are not periodic, but are instead performed according to some other pattern that still ensures that each memory cell is refreshed at least once within a specified time interval.

In accordance with some implementations, in addition to performing refresh operations according to the particular refresh policy, the refresh control logic 112 can also perform on-demand refresh, based on sampling accesses of data performed by the data access logic 107. The on-demand refresh provides additional refresh operations (in addition to regular refresh operations such as periodic refresh operations) to address the issue of repeated disturbances that may have occurred with respect to a particular group of memory cells since the particular group of memory cells was last accessed or refreshed. Note that the refresh commands 114 from the refresh control logic 107 for performing on-demand refresh are different from normal refresh commands for initiating periodic refresh operations. As discussed further below, an on-demand refresh command 114 can target a specific group (or groups) of memory cells, while a periodic refresh command does not target any specific group for groups) of memory cells (instead, the memory device 102 itself can control which group or groups of memory cells is subject to periodic refresh).

The sampling of data access operations by the refresh control logic 112 involves selecting a sample data access operation from among every N data access operations, where N can be a statically or dynamically configured number that is greater than 1. Selecting a sample data access operation from among every N data access operations can be accomplished by skipping N−1 data access operations before selecting a sample data access operation. In some examples, the value of N can be dynamically configured by varying N randomly (such as by using a pseudorandom number generator) after a data access operation has been sampled. Varying the value of N has the effect of causing the sampling rate to change.

The concept of performing on demand refresh based on sampling of data access operations is according to the notion that disturbance of memory cells occurs in the presence of a relatively large number of accesses of neighboring memory cells. In sampling data access operations, it is more likely that data access operations associated with frequently accessed memory locations are encountered (sampled) than data access operations associated with less frequently accessed memory locations. Thus, it is more likely that any given sampled data access operation is to a memory region that is frequently accessed, which would indicate that neighboring memory cells may be subjected to a relatively high rate of disturbance due to data access operations to the frequently accessed memory region.

In accordance with some implementations, in response to a sample at a data access operation of a particular memory region, an on-demand refresh can be performed to memory cells that are near the particular memory region. For example, the memory cells 106 of the memory device 102 can be arranged in banks. In some implementations, upon detecting a sample of a data access operation to a memory location in a particular bank, the refresh control logic 112 generates a refresh command to cause the memory device 102 to refresh the particular bank, or to refresh portions of multiple banks. In some examples, the refresh command can cause all memory locations of the particular bank to be refreshed. In other examples, instead of refreshing the entire bank, the refresh command can cause a refresh to be performed of some portion of the bank, or some other collection of memory locations that are near the memory location of the sampled data access operation.

As noted above, the refresh control logic 112 can be part of the processing circuit 104 that is in a memory controller (which is external of the memory device 102). In other examples, the refresh control logic 112 can be provided in the memory device 102, or alternatively, the refresh control logic 112 can be provided in the requesting device 110, such as a processor or other device.

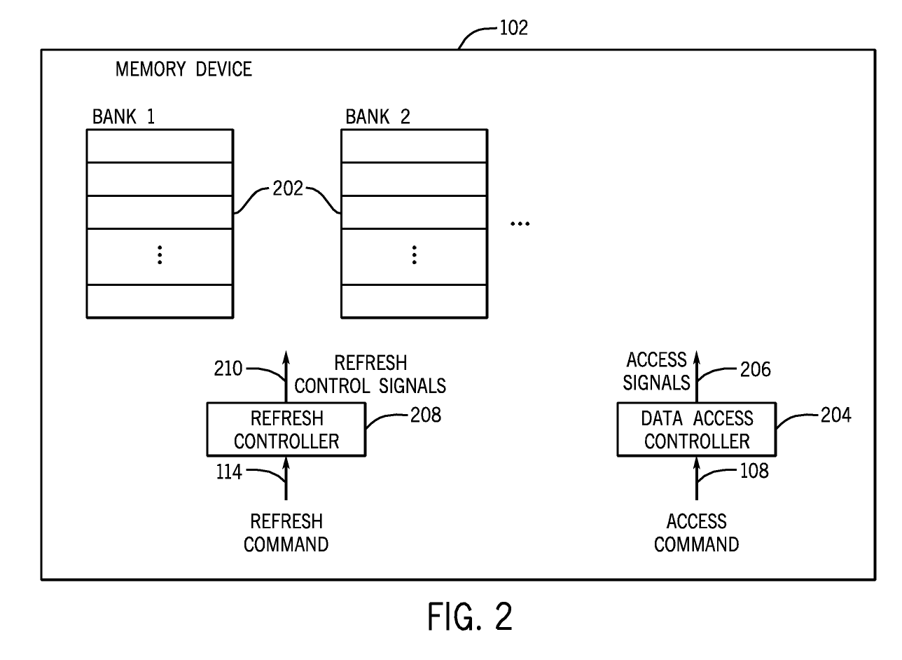

FIG. 2 illustrates an example arrangement of the memory device 102, where the memory cells of the memory device 102 are arranged in banks 202. Just two banks are depicted in the example of FIG. 2. It is noted that more than two banks can be present in the memory device 102.

Each bank 202 includes an array of memory cells, where the array of memory cells includes rows and columns. In a DRAM device, to access a memory location, a row of memory cells in a bank is activated, and a particular column for multiple particular columns) can be selected to output data from the corresponding memory cell(s).

The memory device 102 includes a data access controller 204, which receives the access command 108 from the processing circuit 104 (FIG. 1). In response to the access command 108, the data access controller 204 outputs access signals 206, which are used to select corresponding banks, rows, and columns, based on an address associated with the access command 108.

The memory device 102 further includes a refresh controller 208. The refresh controller 208 receives the refresh command 114 from the refresh control logic 112 of the processing circuit 104 of FIG. 1. Note that the refresh command 114 is an on-demand refresh command different from a periodic refresh command, as noted above. In response to the refresh command 114, the refresh controller 208 can issue refresh control signals 210 to refresh selected memory locations of the memory device 102. In some examples, the refresh command 114 provided by the refresh control logic 112 can identify the bank (or a portion of the tank) that is to be refreshed. In response to the identified bank or bank portion, the refresh controller 208 generates refresh control signals 210 to refresh the identified bank or bank portion. In other examples, the refresh command 114 can identify rows or a range of rows (in a particular bank) to be refreshed, in which case the refresh control signals 210 generated by the refresh controller 208 would cause refresh of the identified rows.

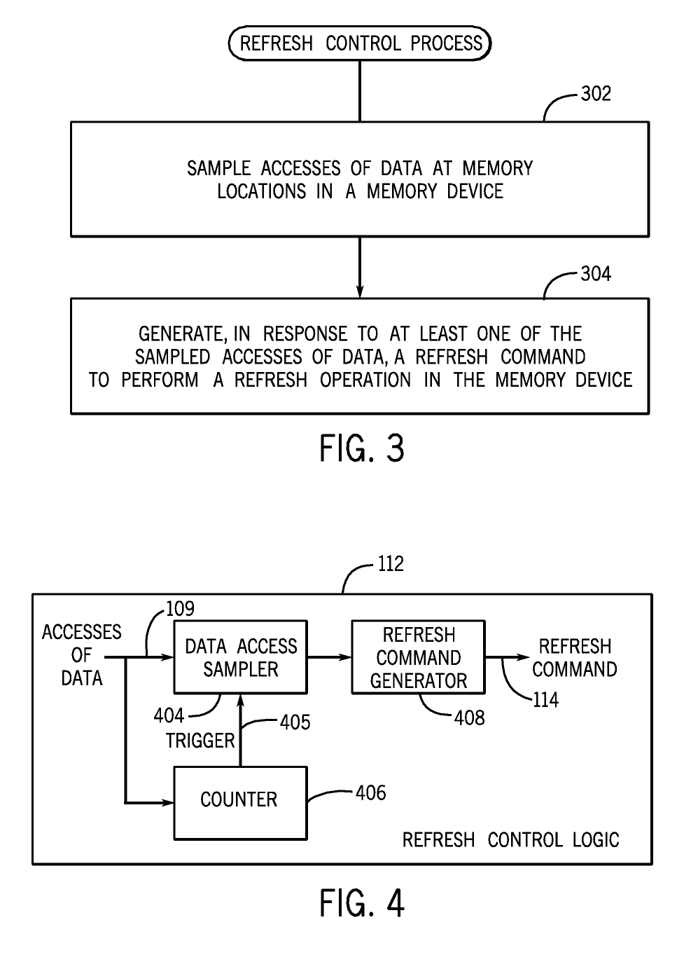

FIG. 3 is a flow diagram of a refresh control process according to some implementations. The process of FIG. 3 can be performed by the refresh control logic 112 of FIG. 1, for example. The refresh control process samples (at 302) accesses of data at memory locations in the memory device 102. Sampling accesses of data involves selecting samples from among a larger collection of accesses of data where the sampling can be performed at a static or dynamically variable sampling rate (e.g. based on he value of N discussed above).

In response to at least one of the sampled accesses of data, the refresh control process generates (at 304) a refresh command to perform a refresh operation in the memory device 102. As discussed above, this refresh command is used to perform on demand refresh that is used for addressing the issue of data corruption that may potentially be caused by disturbances due to data access operations. The on-demand refresh is performed at memory locations that are considered to be near the memory location that is the target of the sampled data access operation.

FIG. 4 is a block diagram of example components the refresh control logic 112. A data access sampler 404 in the refresh control logic 112 receives accesses of data (109), such as from the data access logic 107 of FIG. 1. The data access sampler 404 is to select samples of the received accesses of data (109).

The sampling performed by the data access sampler 404 can be based on an output of a counter 406. The counter 406 may be configured to count the number of accesses of data (109). in response to counting N accesses of data (the counter 406 is considered to have expired), the counter 406 activates a trigger indication 405 to the data access sampler 404. Note that the counter 406 can be initialized with the value N, with the counter 406 decrementing with every detected data access. The counter 406 expires when the counter 406 reaches a predefined low value (e.g. zero). In other examples, the counter 406 can be initialized with a predefined low value (e.g. zero), and is incremented with every detected data access. In this latter example, the counter 406 expires when the counter 406 reaches the value N. When the counter 406 expires, the counter 406 is re-initialized with its initial value to count towards the next activation of the trigger indication 405, to allow for another sample to be collected.

In other implementations, the counter 406 can be a timer that expires after some predefined time duration.

The trigger indication 405 from the counter 406 causes the data access sampler 404 to collect a sample of the accesses of data 109. The selected data access sample is provided to a refresh command generator 408, which produces the refresh command 114 in response to the data access sample. Note that the refresh command generator 408 can issue the refresh command 114 upon receiving the data access sample. Alternatively, the refresh command generator 408 can issue the refresh command 114 at a later time, and the later-generated refresh command 114 can be based on the data access sample as well as other data access samples. Multiple data access samples can be considered by the refresh control logic 112 to determine whether or not the refresh command 114 is warranted, based on a decision of whether the multiple data access samples are likely to cause memory cell disturbance. For example, the refresh control logic 112 can determine that a group of memory cells is likely to be disturbed based on detecting frequency of accesses of neighboring memory cells from the data access samples.

In some implementations, it is assumed that there is just one requesting device 110 and one memory device 102. In other implementations, there can be more than one requesting device 110, and/or there can be more than one memory device 102. In implementations where there are multiple requesting devices 110 and/or multiple memory devices 102, the refresh control logic 112 can be configured to include one or multiple instances of the data access sampler 404 and counter 406, and/or one or multiple instances of the refresh command generator 408.

By using refresh control logic that is able to initiate on-demand refresh operations in response to data access operations, effects of disturbances caused by the data access operations can be mitigated. The on-demand refresh can be performed on regions of the memory device 102 that are near memory locations that are more frequently accessed. In this way, the sampling rate of any given refresh of the memory device 102 can be tuned to the actual disturbance pattern.

In the foregoing description, numerous details are set forth to provide an understanding of the subject disclosed herein. However, implementations may be practiced without some or all of these details. Other implementations may include modifications and variations from the details discussed above. It is intended that the appended claims cover such modifications and variations.

What is claimed is:

1. A method comprising:
sampling, by a processing circuit, a of data at memory locations in a memory device; and
generating, by the processing circuit, a refresh command to perform a refresh operation in the memory device, where generating the refresh command is in response to at least one of the sampled accesses of data.

2. The method of claim 1, wherein sampling the accesses of data comprises selecting a subset of collection of accesses of data at memory locations in the memory device.

3. The method of claim 2, wherein sampling the accesses of data comprises selecting one of the accesses of data in the collection every specified number of the accesses of data in the collection, and wherein the refresh command is generated in response to the selected access of data.

4. The method of claim 3, wherein the refresh command is generated in response to the selected access of data in addition to another sampled access of data.

5. The method of claim 3, further comprising varying the specified number at different times.

6. The method of claim 5, wherein varying the specified number comprise randomly varying the specified number.

7. The method of claim 3, further comprising:
providing a counter to count the specified number, wherein expiration of the counter triggers the selecting of the one access of data; and
re-initializing the counter upon the expiration of the counter to allow triggering of another sample.

8. The method of claim 1, wherein generating the refresh command comprises generating the refresh command that specifies a collection of memory cells in the memory device to refresh.

9. The method of claim 5, wherein the specified collection includes neighbor groups of a group that is accessed by the at least one sampled access of data.

10. The method of claim 1, wherein the processing circuit is included in one of the memory device, a memory controller external to the memory device, or a processor that is to generate requests to access the memory device.

11. An apparatus comprising:
a processing circuit to:
select at least one access of data from among a plurality of accesses of data at memory locations in a memory device; and
generate, in response to the selected at least one access of data, a refresh command to perform a refresh operation in the memory device.

12. The apparatus of claim 11, wherein the refresh operation performed in response to the refresh command is an on-demand refresh operation to address potential disturbance caused by the plurality of accesses of data.

13. The apparatus of claim 12, wherein the refresh operation is in addition to refresh operation performed according to a particular refresh policy that ensures that a given memory cell in the memory device is refreshed at least once every specified time interval.

14. The apparatus of claim 11 wherein the refresh operation is performed in memory cells neighboring a memory location of the selected at least one access of data.

15. A system comprising:
a memory device; and
a memory controller having refresh control logic that includes a counter, wherein the refresh control logic is to:
sample an access of data of the memory device in response to expiration of the counter; and
generate a refresh operation in response to the sampled access of data.
